(19) United States
(12) Patent Application Publication
(10) Pub. No.: US 2025/0132174 A1
(43) Pub. Date: Apr. 24, 2025

(54) PRE-HEAT RINGS, HEATING SYSTEMS, AND PROCESSING CHAMBERS INCLUDING CARBON HEATERS

(71) Applicant: Applied Materials, Inc., Santa Clara, CA (US)

(72) Inventors: Haifeng ZHU, Shanghai (CN); Qinggang ZHOU, Beijing (CN)

(21) Appl. No.: 18/743,694

(22) Filed: Jun. 14, 2024

(30) Foreign Application Priority Data
Oct. 20, 2023 (CN) 202311369783.6

(51) Int. Cl. H01L 21/67; F27B 17/00; H05B 1/02; H05B 3/14; H05B 3/28

(52) U.S. Cl. CPC H01L 21/67109; F27B 17/0025; H01L 21/67248; H05B 1/0233; H05B 3/145; H05B 3/283

(57) ABSTRACT

The present disclosure relates to pre-heat rings including carbon heaters, and related heating systems, methods and processing chambers for semiconductor manufacturing. In one or more embodiments, a pre-heat ring applicable for use in semiconductor manufacturing includes a ring structure, and a carbon heater coupled to the ring structure. The carbon heater has a carbon content that is at least 99% by atomic percentage.

### CROSS-REFERENCE TO RELATED APPLICATION

This application claims priority to China Patent Application Serial No. 202311369783.6, filed Oct. 20, 2023, which is incorporated herein by reference in its entirety.

### BACKGROUND

### Field

The present disclosure relates to pre-heat rings including carbon heaters, and related heating systems, methods and processing chambers for semiconductor manufacturing.

### Description of the Related Art

Semiconductor substrates are processed for a wide variety of applications, including the fabrication of integrated devices and microdevices. During processing, various parameters can affect the uniformity of material deposited on the substrate. For example, the temperature of the substrate and/or temperature(s) of processing chamber component(s) can affect deposition uniformity.

It can be difficult to adjust parameters (such as temperature) for deposition uniformity. Rotation of the substrate, if used, can exacerbate adjustment difficulties. Moreover, adjusting parameters can involve increasing chamber footprints, component contamination, increased cleaning, reduced component lifespan, increased chamber downtime, and reduced throughput.

Therefore, a need exists for improved processing chambers and related components that facilitate temperature uniformity and deposition uniformity.

### SUMMARY

The present disclosure relates to pre-heat rings including carbon heaters, and related heating systems, methods and processing chambers for semiconductor manufacturing.

In one or more embodiments, a pre-heat ring applicable for use in semiconductor manufacturing includes a ring structure, and a carbon heater coupled to the ring structure. The carbon heater has a carbon content that is at least 99% by atomic percentage.

In one or more embodiments, a heating system applicable for use in semiconductor manufacturing includes a ring structure sized and shaped for disposition in a processing chamber, a carbon heater coupled to the ring structure, and a power source configured to electrically connect to the carbon heater.

In one or more embodiments, a processing chamber applicable for use in semiconductor manufacturing includes a chamber body and a plate, the chamber body and the plate at least partially defining a processing volume. The processing chamber includes one or more heat sources configured to heat the processing volume, and a substrate support disposed in the processing volume. The processing chamber includes a pre-heat ring disposed at least partially outwardly of the substrate support. The pre-heat ring includes a ring structure, and a carbon heater coupled to the ring structure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2, is a schematic partial top view of the pre-heat ring and the lower liner shown in FIG. 1, according to one or more embodiments.

FIG. 3 is a schematic perspective view of the pre-heat ring shown in FIG. 2, according to one or more embodiments.

FIG. 4 is a schematic partial top view of a pre-heat ring, according to one or more embodiments.

FIG. 5 is a schematic partial top view of a pre-heat ring, according to one or more embodiments.

FIG. 6 is a schematic partial top view of the processing chamber shown in FIG. 1, according to one or more embodiments.

FIG. 7 is a schematic perspective view of the auxiliary heat source and

the substrate shown in FIG. 1, according to one or more embodiments.

FIG. 8 is a schematic block diagram view of a method of substrate processing for semiconductor manufacturing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to pre-heat rings including carbon heaters, and related heating systems, methods and processing chambers for semiconductor manufacturing.

The disclosure contemplates that terms such as “couples,” “coupling,” “couple,” and “coupled” may include but are not limited to embedding, bonding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

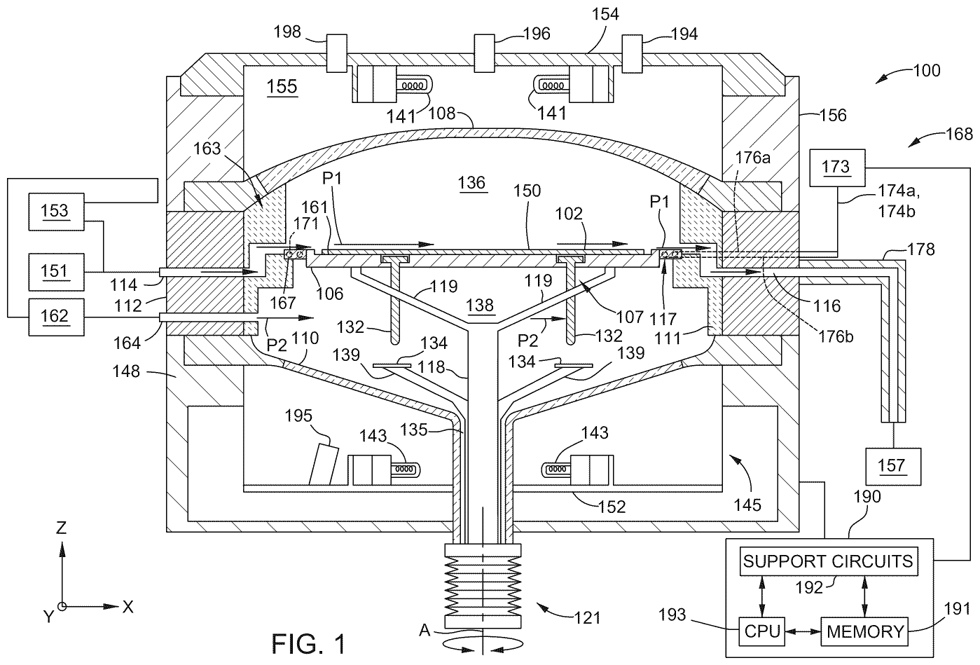

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper plate 108 (such as an upper window, for example an upper dome), a lower plate 110 (such as a lower window, for example a lower dome), a plurality of upper heat sources 141, and a plurality of lower heat sources 143. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper plate 108 and the lower plate 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper plate and a lid 154. The plurality of upper heat sources 141 form a portion of the upper heat source module 155.

The plurality of lower heat sources 143 are disposed between the lower plate 110 and a floor 152. The plurality of lower heat sources 143 form a portion of a lower heat source module 145. The upper plate 108 is an upper dome and/or is formed of an energy transmissive material, such as quartz. The lower plate 110 is a lower dome and/or is formed of an energy transmissive material, such as quartz.

An upper volume 136 and a purge volume 138 are formed between the upper plate 108 and the lower plate 110. The upper volume 136 and the purge volume 138 are part of an internal volume defined at least partially by the upper plate 108, the lower plate 110, and one or more liners 111, 163 of the chamber body. In one or more embodiments, the upper volume 136 is a processing volume.

The internal volume has the substrate support 106 disposed therein. The substrate support 106 includes a top surface 161 on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the upper volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116.

A pre-heat ring 117 is disposed below the one or more gas inlets 114 and the one or more gas exhaust outlets 116. The pre-heat ring 117 is disposed above the one or more purge gas inlets 164. The pre-heat ring 117 is disposed at least partially outwardly of the substrate support 106. The one or more liners 111, 163 are disposed on an inner surface of the flow module 112 and protect the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the upper volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (CI). In one or more embodiments, the one or more process gases P1 include one or more silicon-containing gases (such as silane and/or silicon phosphide (SiP)) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

The processing chamber 100 includes the one or more liners 111, 163 (e.g., a lower liner 111 and an upper liner 163). The lower liner 111 and the upper liner 163 are disposed inwardly of a sidewall (e.g., the flow module 112 and/or the upper body 156) of the chamber body. The flow module 112 (which can be at least part of the sidewall of the processing chamber 100) includes the one or more gas inlets 114 in fluid communication with the upper volume 136. The one or more gas inlets 114 are in fluid communication with one or more flow gaps between the upper liner 163 and a lower liner 111. The one or more of the liners 111, 163 include one or more ledges 167 supporting the pre-heat ring 117.

The pre-heat ring 117 is a temperature-controlled pre-heat ring. The pre-heat ring 117 includes a ring structure 170 and a carbon heater 171 coupled to the ring structure 170. The ring structure 170 is sized and shaped for disposition in the processing chamber 100. The carbon heater 171 has a carbon content that is at least 99% by atomic percentage. In one or more embodiments, the carbon content is at least 99.99% (e.g., 4N or higher) such as at least 99.999% (e.g., 5N or higher), by atomic percentage. The carbon heater 171 is substantially free of metals (such as aluminum and steel). A metal content of the carbon heater 171 is less than 1% by atomic percentage, such as less than 0.1%, for example less than 0.01% or 0.001% or less. In one or more embodiments, the carbon heater 171 is embedded in the ring structure 170. In one or more embodiments, the carbon heater 171 includes a carbon wire. The pre-heat ring 117 is part of a heating system 168 that includes a power source 173 configured to electrically connect to the carbon heater 171 using a pair of electrical lines 174a, 174b. In one or more embodiments, the carbon heater 171 is formed of carbon fiber, graphene, and/or carbon nanotubes.

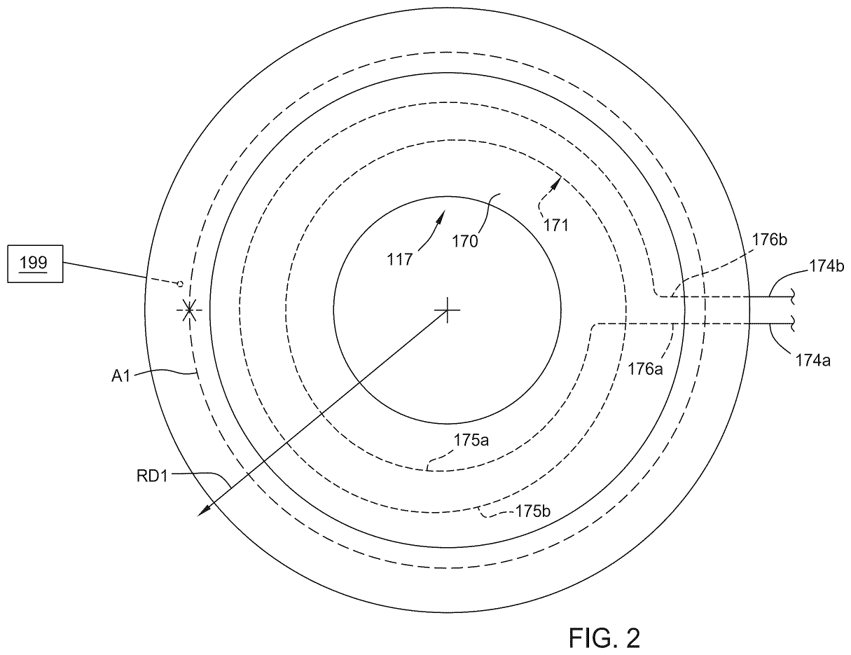

A first electrical line 174a is an input line that supplies electrical current through the carbon heater 171, and a second electrical line 174b is an output line that receives the electrical current from the carbon heater 171. The heating system 168 includes a controller (such as a power dedicated controller or a controller 190) in communication with the power source 173. The controller controls the temperature of the ring structure 170 by controlling a power of electrical energy (such as current) supplied to the carbon heater 171 through the first electrical line 174a. The controller can control the temperature of the ring structure 170 in an open-loop manner or a closed-loop manner. The heating system 168 also includes a temperature sensor (such as one or more of the temperature sensors 195-198) in communication with the controller, and the temperature sensor is configured to measure temperatures of the ring structure 170. In addition to or in place of the temperature sensors 195-198, a temperature sensor 199 (shown in FIG. 2, such as a thermocouple) can be coupled to the ring structure 170 to measure temperatures of the ring structure 170. The thermocouple can be at least partially embedded in the ring structure 170. The controller can receive the temperature measurements of the ring structure 170 and control (such as alter) the power supplied by the power source 173 to control (such as adjust) the temperature of the ring structure 170. As an example, the controller can compare measure temperature(s) of the ring structure 170 to a target temperature and adjust the power supplied by the power source 173 based on the target temperature. The target temperature can be stored in a memory (such as the memory 191 of the controller 190 described below).

In one or more embodiments, an auxiliary heat source 194 is used in addition to the carbon heater 171 and the heat sources 141, 143. In one or more embodiments, the auxiliary heat source 194 includes a laser source (such as a collimated laser source), the heat sources 141, 143 include lamps, and the carbon heater 171 includes a resistive heater.

During a deposition operation (e.g., an epitaxial growth operation), the one or more process gases P1 flow through the one or more gas inlets 114, through the one or more gaps, and into the upper volume 136 to flow over the substrate 102. During the deposition operation, the carbon heater 171 is used to heat the ring structure 170. The one or more process gases P1 flow over the ring structure 170, which pre-activates the one or more process gases P1 for depositing film on the substrate 102 prior to flowing over the substrate 102. The heating of the ring structure 170 facilitates deposition of film at an outer region (such as an edge region) of the substrate 102, which facilitates deposition uniformity (such as center-to-edge uniformity). The carbon heater 171 facilitates deposition uniformity while facilitating reduced particle contamination of the substrate 102 and/or reduced degradation of chamber components (such as the ring structure 170 and/or the one or more liners 111, 163).

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the upper volume 136.

The processing system includes one or more sensors 195, 196, 198 (e.g., temperature sensors) configured to measure parameter(s) (e.g., temperature(s)) within the processing chamber 100. In one or more embodiments, the one or more sensors 195, 196, 198 include a central sensor 196 and one or more outer sensors 195, 198. The controller 190 (described below) can control the one or more sensors 195, 196, 198, 199, the carbon heater 171, and/or one or more heat sources 141, 143, and can conduct method(s) of adjusting uniformity of substrate processing using at least one of the one or more sensors 195, 196, 198, 199, the carbon heater 171, and/or one or more heat sources 141, 143. In one or more embodiments, one or more sensors 195, 196, 198 each include a pyrometer, such as a pyrometer that includes a silicon sensor. In one or more embodiments, each sensor 195, 196, 198 is an optical sensor, such as an optical pyrometer. The present disclosure contemplates that sensors other than pyrometers may be used, and/or one or more of the sensors 195, 196, 198 can measure properties other than temperature.

In one or more embodiments, the sensors 195, 196, 198 include one or more upper sensors 196, 198 disposed above the substrate 102 and adjacent the lid 154, and one or more lower sensors 195 disposed below the substrate 102 and adjacent the floor 152. The present disclosure contemplates that at least one of the one or more lower sensors 195 can be vertically aligned below at least one of the upper sensors 196, 196 (such as outer sensor 198).

Each sensor 195, 196, 198, can be a single-wavelength sensor device or a multi-wavelength (such as dual-wavelength) sensor device. In one or more embodiments, the system including the process chamber 100 includes any one, any two, or any three of the four illustrated sensors 195, 196, 198. In one or more embodiments, the process chamber 100 includes one or more additional sensors, in addition to the sensors 195, 196, 198. In one or more embodiments, the process chamber 100 may include sensors disposed at different locations and/or with different orientations than the illustrated sensors 195, 196, 198.

As shown, a controller 190 is in communication with the processing chamber 100 and is used to control processes and methods, such as the operations of the methods described herein.

The controller 190 is configured to receive data or input as sensor readings from sensor(s) (such as one or more of the sensors 195, 196, 198, 199). The sensors can include, for example: sensors that monitor growth of layer(s) on the substrate 102; and/or sensors that monitor temperatures of the ring structure 170, the substrate 102, the substrate support 106, and/or the liners 111, 163. The controller 190 is equipped with or in communication with a system model of the processing chamber 100. The system model includes a heating model, a temperature uniformity model, a film uniformity model, a film deposition rate model, a coating model, a rotational position model, and/or a gas flow model. The system model is a program configured to estimate parameters (such as a signal profile (e.g., a temperature profile) of the substrate 102 and/or the substrate support 106, a gas flow rate, a gas pressure, a rotational position of component(s), a heating profile, a coating condition, and/or a cleaning condition) within the processing chamber 100 throughout a deposition operation and/or a cleaning operation. The controller 190 is further configured to store readings and calculations. The readings and calculations include previous sensor readings, such as any previous sensor readings within the processing chamber 100. The readings and calculations further include the stored calculated values from after the sensor readings are measured by the controller 190 and run through the system model. Therefore, the controller 190 is configured to both retrieve stored readings and calculations as well as save readings and calculations for future use. Maintaining previous readings and calculations enables the controller 190 to adjust the system model over time to reflect a more accurate version of the processing chamber 100.

The controller 190 can monitor heating, generate a signal profile (e.g., a temperature profile), identify set(s) of one or more heat sources, adjust a heating profile, adjusting heating power(s) (such as the power supplied by the power source 173), estimate an optimized parameter (such as the target temperature), adjust the one or more sensors 195-199, generate an alert on a display, halt a deposition operation, initiate a chamber downtime period, delay a subsequent iteration of the deposition operation, initiate a cleaning operation, halt the cleaning operation, and/or otherwise adjust the process recipe.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., target temperature(s) for the ring structure 170 and/or the substrate 102, reading(s), signal difference(s), signal profile(s), heating power(s) (e.g., applied to the carbon heater 171 and/or one or more of the heat sources 141, 143), adjustment factor(s), threshold ratio(s), range(s) and/or training range(s) with which the signal difference(s) are compared, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of the operations described herein (such as the deposition operation) to be conducted in relation to the processing chamber 100. The controller 190 and the processing chamber 100 are at least part of a system for processing substrates.

The various operations described herein (such as operations of the method 800) can be conducted automatically using the controller 190, or can be conducted automatically or manually with certain operations conducted by a user.

In one or more embodiments, the controller 190 includes a mass storage device, an input control unit, and a display unit. The controller 190 can monitor the temperature of the ring structure 170, the temperature of the substrate 102, the temperature of the substrate support 106, the process gas flow, and/or the purge gas flow. In one or more embodiments, the controller 190 includes multiple controllers 190, such that the stored readings and calculations and the system model are stored within a separate controller from the controller 190 which controls the operations of the processing chamber 100. In one or more embodiments, all of the system model and the stored readings and calculations are saved within the controller 190.

The controller 190 is configured to control the deposition, the cleaning, the rotational position, the heating, and gas flow through the processing chamber 100 by providing an output to the controls for the sensors 195, 196, 198, 199, the power source 173, the upper heat sources 141, the lower heat sources 143, the process gas source 151, the purge gas source 162, the motion assembly 121, and/or the exhaust pump 157.

The controller 190 is configured to adjust the output to the controls based on the sensor readings, the system model, and the stored readings and calculations. The controller 190 includes embedded software and a compensation algorithm to calibrate measurements. The controller 190 can include one or more machine learning algorithms and/or artificial intelligence algorithms that estimate optimized parameters (such as the target temperature(s) for the ring structure 170 and/or the substrate 102) for the uniformity analysis operations, the deposition operations, and/or the cleaning operations.

The one or more machine learning algorithms and/or artificial intelligence algorithms may implement, adjust and/or refine one or more algorithms, inputs, outputs or variables described above. Additionally or alternatively, the one or more machine learning algorithms and/or artificial intelligence algorithms may rank or prioritize certain aspects of adjustments of the process chamber 100 and/or method(s) relative to other aspects of the process chamber 100 and/or method(s) (such as the method 800). The one or more machine learning algorithms and/or artificial intelligence algorithms may account for other changes within the processing systems such as hardware replacement and/or degradation. In one or more embodiments, the one or more machine learning algorithms and/or artificial intelligence algorithms account for upstream or downstream changes that may occur in the processing system due to variable changes of the process chamber 100 and/or method(s). For example, if variable “A” is adjusted to cause a change in aspect “B” of the process, and such an adjustment unintentionally causes a change in aspect “C” of the process, then the one or more machine learning algorithms and/or artificial intelligence algorithms may take such a change of aspect “C” into account. In such an embodiment, the one or more machine learning algorithms and/or artificial intelligence algorithms embody predictive aspects related to implementing the process chamber 100 and/or the method(s). The predictive aspects can be utilized to preemptively mitigate unintended changes within a processing system.

The one or more machine learning algorithms and/or artificial intelligence algorithms can use, for example, a regression model (such as a linear regression model) or a clustering technique to estimate optimized parameters. The algorithm can be unsupervised or supervised. The one or more machine learning algorithms and/or artificial intelligence algorithms can optimize, for example, optimized parameters such as target temperature(s), reading(s), signal difference(s), signal profile(s), heating power(s), adjustment factor(s), threshold ratio(s), range(s), and/or training range(s) with which the signal difference(s) are compared, a cleaning recipe, and/or a processing recipe.

In one or more embodiments, the controller 190 automatically conducts the operations described herein without the use of one or more machine learning algorithms and/or artificial intelligence algorithms. In one or more embodiments, the controller 190 compares measurements (such as readings and/or signal differences for temperature measurements) to data in a look-up table and/or a library to identify a set of one or more heat sources and/or adjust a heating power for the carbon heater 171. The controller 190 can stored measurements as data in the look-up table and/or the library.

FIG. 2, is a schematic partial top view of the pre-heat ring 117 and the lower liner 111 shown in FIG. 1, according to one or more embodiments.

In one or more embodiments, the carbon wire of the carbon heater 171 is disposed (e.g., embedded) in the ring structure 170. In one or more embodiments, the carbon heater 171 includes the carbon wire disposed (e.g., embedded) in a conduit (such as a pipe or other structure) disposed in the ring structure 170. The carbon wire and the conduit (if used) include a plurality of arcuate sections 175a, 175b that are spaced from each other along a radial direction RD1. The carbon wire includes a pair of electrode sections 176a, 176b extending out of the ring structure 170. The conduit (if used) can be disposed about the pair of electrode sections 176a, 176b. The pair of electrode sections 176a, 176b extend outwardly through the one or more liners 111, 163 and through the chamber body (e.g., through the flow module 112) to an outside of the processing chamber 100. The ring structure 170 and/or the conduit (if used) enclose the carbon wire.

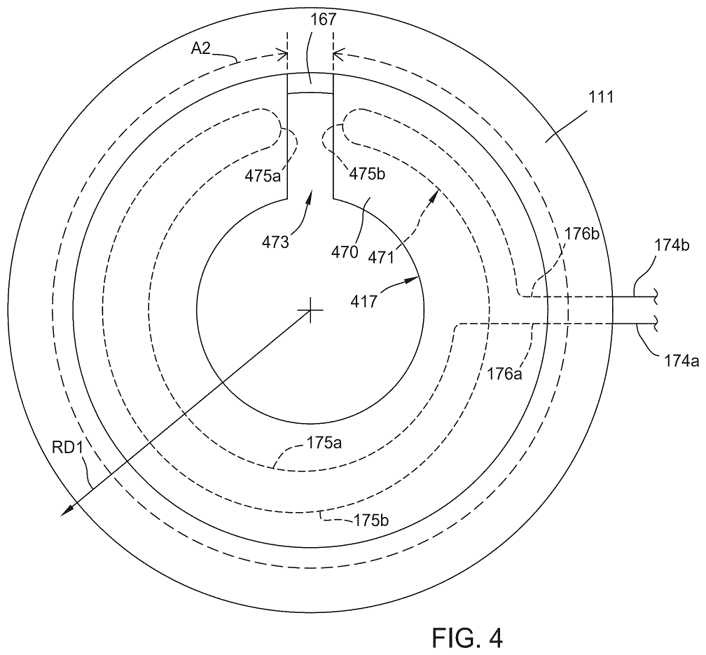

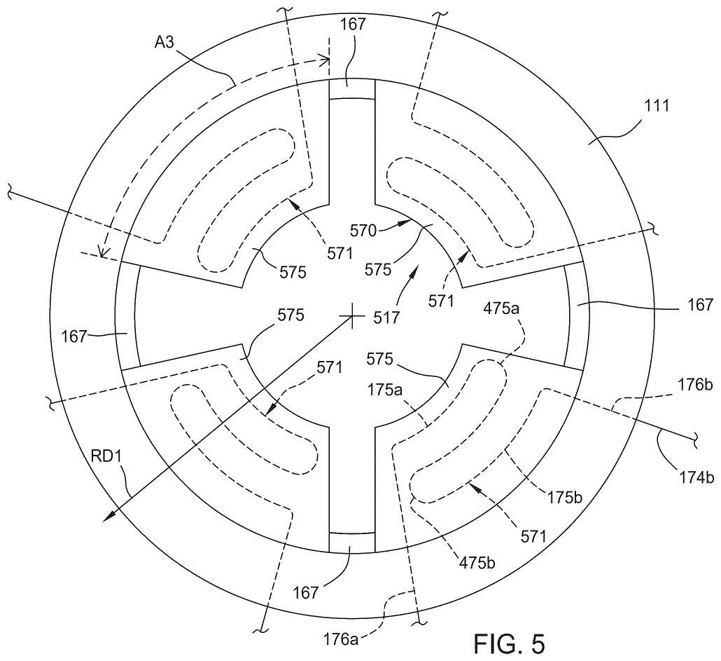

The ring structure 170 is formed of one of more of: quartz (such as a transparent quartz or an opaque quartz, for example white quartz, grey quartz, and/or black quartz), silicon carbide (SiC), graphite (such as graphite coated with SiC), or one or more ceramic materials. The one or more ceramic materials can include, for example, alumina (aluminum oxide (Al₂O₃)), aluminum nitride (AlN), silicon nitride (SiN, for example Si₃N₄), boron nitride (BN), and/or boron carbide (B₄C)). In one or more embodiments, the ring structure 170 is formed of an opaque material. In one or more embodiments, the ring structure 170 is formed of SiC. The conduit (if used) is formed of one of more of: quartz (such as a transparent quartz or an opaque quartz, for example white quartz, grey quartz, and/or black quartz), SiC, graphite (such as graphite coated with SiC), or the one or more ceramic materials. In one or more embodiments, the conduit is formed of a transparent material. In one or more embodiments, the conduit is formed of transparent quartz and/or one or more ceramic materials. In one or more embodiments, the ring structure 170 includes a complete ring body having an azimuthal angle A1 equal to 360 degrees (as shown in FIG. 2). The present disclosure contemplates that the ring structure 170 can include one or more ring segments (as shown in FIGS. 4-5).

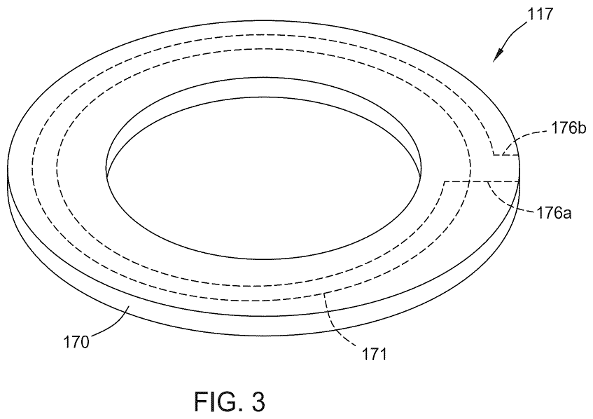

FIG. 3 is a schematic perspective view of the pre-heat ring 117 shown in FIG. 2, according to one or more embodiments.

FIG. 4 is a schematic partial top view of a pre-heat ring 417, according to one or more embodiments. The pre-heat ring 417 is similar to the pre-heat ring 117, and includes one or more aspects, features, components, operations, and/or properties thereof. The pre-heat ring 417 can be used in place of the pre-heat ring 117 shown in FIGS. 1-3, according to one or more embodiments. A ring structure 470 of the pre-heat ring 417 includes a notch 473 such that a portion of the ledge 167 is visible from the top view, and the pre-heat ring 417 includes a carbon heater 471. The carbon heater 471 includes a set of turns 475a, 475b on opposing sides of the notch 473. In one or more embodiments, the ring structure 470 includes a single ring segment that includes the notch 473. The ring segment of the ring structure 470 has an azimuthal angle A2 less than 360 degrees, such as within a range of 1 degree to 15 degrees.

The present disclosure contemplates that the notch 473 can be wider, and the azimuthal angle A2 can be smaller (such as within a range of 180 degrees to 340 degrees) such that the ring segment is a C-ring.

FIG. 5 is a schematic partial top view of a pre-heat ring 517, according to one or more embodiments. The pre-heat ring 517 is similar to the pre-heat ring 117, and includes one or more aspects, features, components, operations, and/or properties thereof. The pre-heat ring 517 can be used in place of the pre-heat ring 117 shown in FIGS. 1-3, according to one or more embodiments. A ring structure 570 of the pre-heat ring 517 includes a plurality of ring segments 575 spaced from each other along an arcuate (e.g., circular) profile, and the pre-heat ring 517 includes a plurality of carbon heaters 571. In one or more embodiments, a carbon heater 571 is coupled to (e.g., embedded in) each ring segment 575. In one or more embodiments, the ring segments 575 respectively have an azimuthal angle A3 less than 360 degrees, such as less than 90 degrees.

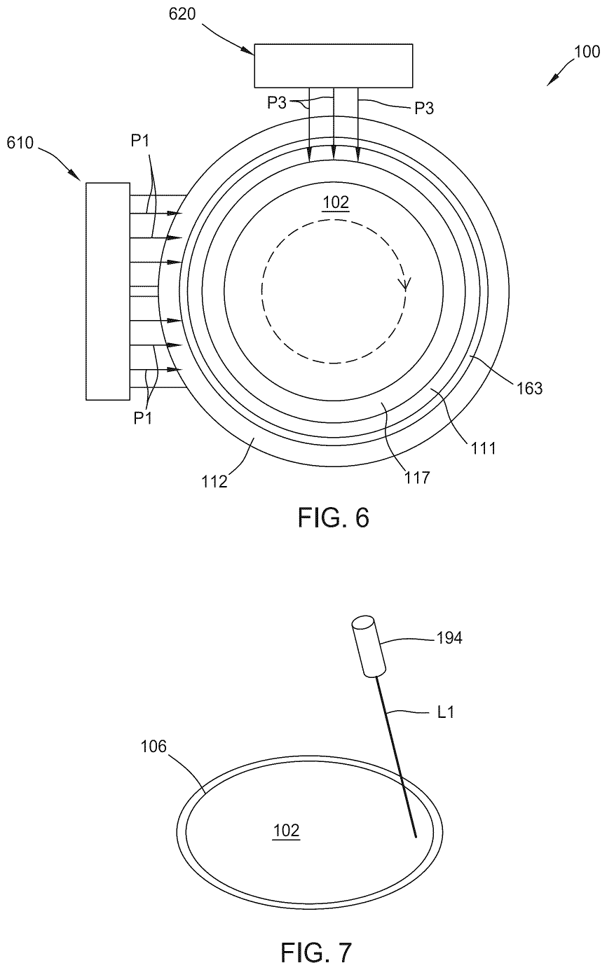

FIG. 6 is a schematic partial top view of the processing chamber 100 shown in FIG. 1, according to one or more embodiments.

The processing chamber 100 includes a primary inject manifold 610 that supplies the one or more process gases P1, and a side inject manifold 620 that supplies one or more second process gases P3. The one or more second process gases P3 can have the same composition as or a different composition than the one or more process gases P1. The primary inject manifold 610 can supply the one or more process gases P1 in a plurality of zones across the substrate 102 (six zones are shown in FIG. 6). The present disclosure contemplates that a different number (such as one, two, three, four, five, or seven or more) of zones can be used for the primary inject manifold 610. The side inject manifold 620 can supply the one or more second process gases P3 in a plurality of zones.

FIG. 7 is a schematic perspective view of the auxiliary heat source 194 and the substrate 102 shown in FIG. 1, according to one or more embodiments.

In one or more embodiments, the auxiliary heat source 194 directs light L1 (e.g., laser light) toward a section of an outer region (e.g., an edge region) of the substrate 102 and/or the substrate support 106. The auxiliary heat source 194 can direct the light L1 toward the ring structure 170 of the pre-heat ring 117. The auxiliary heat source 194 and the carbon heater 171 can be controlled by the controller to correct for one or more temperature non-uniformities and/or deposition non-uniformities along the substrate 102. For example, a temperature of an outer region (such as an edge region) of the substrate 102 can be increased to increase a thickness of film deposited on the outer region.

The auxiliary heat source 194 and the carbon heater 171 can be used in conjunction with the primary inject manifold 610 and/or the side inject manifold 620. In addition to controlling the auxiliary heat source 194 and/or the carbon heater 171, the controller can control the composition and/or flow rates of gas supplied to the zones of the primary inject manifold 610 and/or the side inject manifold 620 to correct for one or more temperature non-uniformities and/or deposition non-uniformities along the substrate 102.

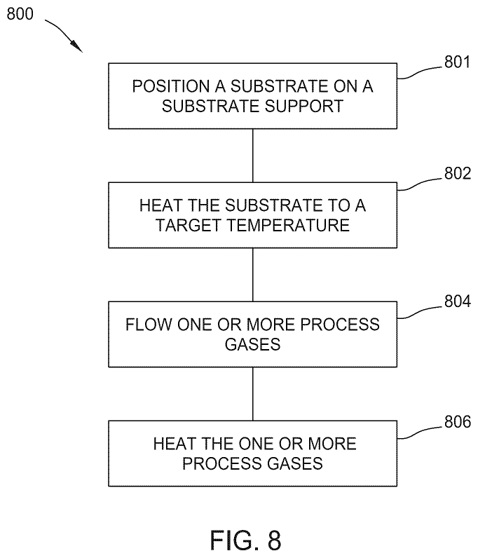

FIG. 8 is a schematic block diagram view of a method 800 of substrate processing for semiconductor manufacturing, according to one or more embodiments.

Operation 801 includes positioning a substrate on a substrate support in a processing volume of a processing chamber. In one or more embodiments, the positioning includes moving a substrate support and/or a plurality of lift pins relative to each other to land the substrate on the substrate support.

Operation 802 of the method 800 includes heating the substrate to a target temperature. In one or more embodiments, the target temperature is less than 500 degrees Celsius. In one or more embodiments, the target temperature is 400 degrees Celsius or less. Other target temperatures are contemplated.

Operation 804 includes flowing one or more process gases.

Operation 806 includes heating the one or more process gases. The heating can include pre-heating. The one or more process gases flow over one or more of the heaters described herein (such as pre-heat ring 117 including the carbon heater 171), which heats the one or more process gases and activates the one or more process gases. The one or more process gases then flow over the substrate to form one or more layers on the substrate. The heating can include controlling (e.g., adjusting) the temperature of the heater(s) by controlling a power of an electrical energy. The controlling of the temperature can be conducted in response to one or more measurements (such as one or more temperature measurements of the heater(s)).

Benefits of the present disclosure include adjustability of parameters (such as temperatures, gas flow paths, gas flow rates, and/or gas pressures) across a variety of operation conditions; reduced temperature non-uniformities; reduced deposition non-uniformities; enhanced film growth rates (e.g., at outer regions of substrates); enhanced device performance; limited parametric yield; increased chamber component lifespans; reduced cleaning; reduced chamber downtime; and increased throughput.

As an example, the carbon heaters of the pre-heat rings described herein facilitate enhancing temperature uniformity and deposition uniformity for the substrate 102 in a manner that facilitates reduced degradation and/or contamination of the pre-heat rings, the substrate support 106, and/or the liners 111, 163.

It is contemplated that one or more aspects disclosed herein may be combined. As an example, one or more aspects, features, components, operations and/or properties of the processing chamber 100, the controller 190, the substrate support 106, the pre-heat ring 117, the lower liner 111, the upper liner 163, the pre-heat ring 417, the pre-heat ring 517, the primary inject manifold 610, the side inject manifold 620, the auxiliary heat source 194, the method 800, and/or the operations described for the deposition operation in relation to FIG. 1 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A pre-heat ring applicable for use in semiconductor manufacturing, the pre-heat ring comprising:
a ring structure; and
a carbon heater coupled to the ring structure, the carbon heater having a carbon content that is at least 99% by atomic percentage.

2. The pre-heat ring of claim 1, wherein the carbon heater includes a carbon wire disposed in the ring structure or a conduit disposed in the ring structure.

3. The pre-heat ring of claim 2, wherein the ring structure is formed of one of more of: quartz, graphite, silicon carbide (SiC), or one or more ceramic materials.

4. The pre-heat ring of claim 2, wherein the carbon wire comprises a plurality of arcuate sections that are spaced from each other along a radial direction.

5. The pre-heat ring of claim 4, wherein the carbon wire further comprises a pair of electrode sections extending out of the ring structure.

6. The pre-heat ring of claim 1, wherein the ring structure comprises a complete ring body having an azimuthal angle equal to 360 degrees.

7. The pre-heat ring of claim 1, wherein the ring structure comprises one or more ring segments having an azimuthal angle less than 360 degrees.

8. The pre-heat ring of claim 1, wherein the carbon content is at least 99.999% by atomic percentage.

9. The pre-heat ring of claim 8, wherein the ring structure is formed of SiC.

10. A heating system applicable for use in semiconductor manufacturing, the heating system comprising:
a ring structure sized and shaped for disposition in a processing chamber;
a carbon heater coupled to the ring structure; and
a power source configured to electrically connect to the carbon heater.

11. The heating system of claim 10, further comprising a controller in communication with the power source.

12. The heating system of claim 11, further comprising a temperature sensor in communication with the controller, the temperature sensor configured to measure temperatures of the ring structure.

13. The heating system of claim 10, wherein the carbon heater includes a carbon wire disposed in the ring structure or a conduit disposed in the ring structure.

14. The heating system of claim 13, wherein the carbon wire comprises a plurality of arcuate sections that are spaced from each other along a radial direction.

15. The heating system of claim 14, wherein the carbon wire further comprises a pair of electrode sections extending out of the ring structure.

16. The heating system of claim 10, wherein the carbon heater has a carbon content that is at least 99.999% by atomic percentage.

17. A processing chamber applicable for use in semiconductor manufacturing, comprising:
a chamber body;
a plate, the chamber body and the plate at least partially defining a processing volume;
one or more heat sources configured to heat the processing volume;
a substrate support disposed in the processing volume; and
a pre-heat ring disposed at least partially outwardly of the substrate support, the pre-heat ring comprising:
a ring structure, and
a carbon heater coupled to the ring structure.

18. The processing chamber of claim 17, wherein the chamber body comprises a liner disposed inwardly of a sidewall, the liner comprising one or more ledges supporting the pre-heat ring.

19. The processing chamber of claim 18, wherein the carbon heater includes a carbon wire disposed in the ring structure or a conduit disposed in the ring structure, and the carbon wire comprises:
a plurality of arcuate sections that are spaced from each other along a radial direction; and
a pair of electrode sections extending out of the ring structure and outwardly through the chamber body.

20. The processing chamber of claim 17, wherein the carbon heater has a carbon content that is at least 99.999% by atomic percentage.
